(19) United States
(12) Patent Application Publication
(10) Pub. No.: US 2005/0199998 A1
(43) Pub. Date: Sep. 15, 2005

(54) Semiconductor package with heat sink and method for fabricating the same and stiffener

(75) Inventors: Chin-Te Chen, Taichung (TW); Wen-Che Lee, Taichung (TW); Chang-Fu Lin, Taichung (TW)

Correspondence Address: Mr. Peter F. Corless;EDWARDS & ANGELL, LLP, 101 Federal Street, Boston, MA, 02110, US

(73) Assignee: Siliconware Precision Industries Co., Ltd.

(21) Appl. No.: 10/861,544

(22) Filed: Jun. 4, 2004

(30) Foreign Application Priority Data
Mar. 9, 2004 (TW) 093106123

(51) Int. Cl. H01L 23/28

(52) U.S. Cl. 257/706; 257/707; 257/712

(57) ABSTRACT

A semiconductor package with a heat sink, a method for fabricating the same and a stiffener for the semiconductor package are proposed. At least one chip and the stiffener surrounding the chip are mounted on a substrate, and the heat sink is respectively attached to a non-active surface of the chip and the stiffener. A plurality of penetrating openings are formed on the stiffener, and an adhesive is filled in the penetrating openings to enhance the bonding strength of the heat sink and the stiffener, thereby inhibiting the heat sink and the stiffener from coming off.

### FIELD OF THE INVENTION

The present invention relates to semiconductor packages with a heat sink and methods for fabricating the same, and more particularly, to a semiconductor package with a heat sink for increasing the bonding strength of the heat sink, and a method for fabricating the same and the stiffener thereof.

### BACKGROUND OF THE INVENTION

A Flip-Chip Ball Grid Array (FCBGA) is a type of semiconductor package combining Flip-Chip structure and Ball Grid Array structure, allowing at least one semiconductor chip to be electrically connected to one surface of a substrate via a plurality of conductive solder bumps in an upside-down manner and a plurality of solder balls to be mounted on the other side of the substrate for electrically connecting the semiconductor package to external devices. This type of semiconductor package is highly desirable because the overall size of the semiconductor package can be significantly reduced, and, moreover, conventional wire-bonding is not required, thereby eliminating a source of signal interference and loss during signal transmission, ensuring that this type of package will become the most popular semiconductor packages in the next generation.

Because of its superior characteristics, this FCBGA semiconductor package is widely used for highly integrated semiconductor chips. However, one of the limitations of this package is that the amount of heat generated is relatively higher than conventional packages. Heat dissipation efficiency thus becomes one of the most critical factors in determining the yield for the semiconductor products employing this package design.

In a typical FCBGA package, heat dissipation is effected by attaching a heat sink which has a larger area than the semiconductor to a substrate via an adhesive or a solder material, allowing the heat generated by the flipchip to be transferred from the non-active surface of the chip to the heat sink and subsequently dissipated to the ambient environment. For example, as shown in FIG. 6, a conventional semiconductor package with a heat sink disclosed by U.S. Pat. No. 5,311,402 attaches the heat sink 41 to the substrate 40 by firstly forming a plurality of grooves 40a on the substrate 40 and inserting the supporting portion 41a of the heat sink 41 into the corresponding grooves 40a in order to firmly attach the heat sink to the substrate. A drawback of this attaching method, however, is that the attaching area between the heat sink 41 and the substrate 40 is quite small, which often presents a risk of a weak adhesion between the heat sink 41 and the substrate 40. When other passive components for improving electrical performance are also mounted on the substrate 40, the attaching area between the heat sink 41 and the substrate 40 is further reduced, and it is quite possible that the heat sink 41 detaches during shock testing or shaking as a result weak adhesion. Moreover, the formation of grooves on the substrate 40 to increase the attachment area not only complicates the manufacturing procedure, but also damages the structure of the substrate 40, causing reliability concerns. Another problem associated with this is that in order to directly attach the heat sink 41 to the substrate, the heat sink must be formed with a supporting portion 41a extending downwardly for attachment. This no doubt complicates the manufacturing procedure as well as increases the manufacturing cost. In addition, since the coefficient of thermal expansion between the heat sink 41 material and the substrate 40 material differ considerably, it is possible that semiconductor package will suffer from warpage or delamination, as a result of a difference in thermal stress during the temperature cycles in the latter manufacturing procedures.

Accordingly, in order to overcome the foregoing problems of warpage and delamination, U.S. Pat. No. 5,909,056 proposes another design to attach the heat sink to the substrate. As shown in FIG. 7, the heat sink 51 is attached to a ring stiffener 52 provided on the substrate 50, and, subsequently using epoxy, a tab or sealing material, attaching the heat sink 51 to the semiconductor chip. This design employing a stiffener 52, desirably reduces the occurrence of warpage, but the attachment of the heat sink 51 to the substrate 50 still only relies on the small surface area of the stiffener 52 and the chip 53, which are not sufficient to ensure that the heat sink does not come off during latter testing or when experiencing shaking.

In order to solve this problem, U.S. Pat. No. 6,093,961 further proposes a semiconductor package with a heat sink having inwardly turned flanges 61a that engage with the semiconductor chip, as shown in FIG. 8, thereby fixing the heat sink 61 in position and desirably increasing the bonding strength of the heat sink 61. However, this arrangement does not address the large difference in the thermal expansion coefficient (CTE) between the heat sink 61 and the chip 62, and, as a result, it is likely that the semiconductor chip 62 may suffer from cracking during high temperature procedures or reliability testing.

Alternatively, in prior art, the heat sink can be fixed on the substrate using a clamping means. For example, as shown in FIG. 9, U.S. Pat. No. 5,396,403 discloses a semiconductor package having a heat sink 72 that is fastened to a support plate by screws, so as to mount the heat sink firmly on the substrate 70. However this addition of the clamping means (such as screws and support plate) requires forming openings 70a on the heat sink 72 and the support plate, further increasing the manufacturing cost. Moreover if any stray particles, moisture outside the package get into the semiconductor package through the openings, the semiconductor package can be seriously impaired, resulting in a low yield.

Thus, there exists a need to develop a semiconductor package having a heat sink and a method of fabricating such a semiconductor package that the bonding of the heat sink to the substrate is strengthened while maintaining a low manufacturing cost, simplified processing, and high yield for the product.

### SUMMARY OF THE INVENTION

A primary objective of the present invention is to provide a semiconductor package with a heat sink, a method of fabricating the same and a stiffener thereof, in which the bonding of the heat sink to the substrate is sufficient to prevent it from coming off.

Another objective of the invention is to provide a semiconductor package with a heat sink utilizing a stiffener and a method for fabricating the same, with simplified manufacturing procedures and low manufacturing cost.

Further another objective of the invention is to provide a semiconductor package with a heat sink utilizing a stiffener and a method for fabricating the same, in which the heat sink can be firmly attached on the substrate without interfering with the patterned circuits on the substrate.

Yet another objective of the invention is to provide a semiconductor package with a heat sink utilizing a stiffener and a method of fabricating the same, in which the problem of warpage and chip cracking can be prevented.

In order to achieve the foregoing and other objectives, the semiconductor package with the heat sink of the invention comprises: a substrate having a first surface and an opposing second surface; at least one chip having an active surface and an opposing non-active surface attached and electrically connected to the substrate; at least one stiffener having a plurality of penetrating openings, mounted on the first surface of the substrate to embrace the semiconductor chip; a heat sink attached on the stiffener; and an adhesive which is used to respectively attach the stiffener to the substrate and the heat sink to the stiffener, and fill in each of the penetrating openings.

The fabricating method of the foregoing semiconductor package with the heat sink comprises the steps of: preparing a substrate having a first surface and an opposing second surface; preparing a stiffener formed with a plurality of penetrating openings thereon; applying an adhesive to attach the stiffener to the substrate and filling in the penetrating openings in a way that a defined area is formed by the surrounding stiffener on the first surface of the substrate; preparing at least one chip which is attached to the defined area surrounded by the stiffener on the first surface of the substrate via its active surface and electrically connected to the substrate; and applying an adhesive on the stiffener and also filling the penetrating openings with the adhesive to attach the heat sink to the stiffener.

The foregoing penetrating openings formed on the stiffener penetrate from the first surface of the substrate to the bottom surface of the heat sink. The formation of the penetrating openings is achieved by using a punch, the size, number, and shape of the openings not being limited to a particular design, and can be changed accordingly. The heat sink can be also formed with such openings to allow the adhesive to be filled therein.

Accordingly, the bonding strength of the heat sink to the substrate is enhanced via the adhesive filling in the penetrating openings, thereby preventing the heat sink from coming off during latter fabricating processes, while simplifying the fabricating procedures and reducing the manufacturing cost.

### BRIEF DESCRIPTION OF THE DRAWINGS

The invention can be more fully understood by reading the following detailed description of the preferred embodiments, with reference made to the accompanying drawings, wherein:

FIG. 1 is a schematic diagram of a semiconductor package with a heat sink in accordance with the present invention;

FIG. 2 is a top view of a ring stiffener having a plurality of penetrating openings thereon in accordance with the present invention;

FIG. 3A to FIG. 3F compose a fabrication chart of the semiconductor package with the heat sink in accordance with the present invention;

FIG. 4 is a cross-sectional view of the semiconductor package with the heat sink in accordance with the second preferred embodiment of the invention;

FIG. 5 is a top view of the ring stiffener in accordance with another preferred embodiment of the present invention;

FIG. 6 (PRIOR ART) is a cross-sectional view of a conventional semiconductor package with a heat sink as disclosed by U.S. Pat. No. 5,311,402;

FIG. 7 (PRIOR ART) is a cross-sectional view of a conventional semiconductor package with a heat sink as disclosed by U.S. Pat. No. 5,909,056;

FIG. 8 (PRIOR ART) is a cross-sectional view of a conventional semiconductor package with a heat sink as disclosed by U.S. Pat. No. 6,093,961; and

FIG. 9 (PRIOR ART) is a cross-sectional view of a conventional semiconductor package with a heat sink as disclosed by U.S. Pat. No. 5,396,403.

### DETAILED DESCRIPTION OF THE PREFERRED EMBODIMENTS

FIG. 1 is a schematic diagram of a semiconductor package with a heat sink in accordance with a preferred embodiment of the invention. As shown in the drawing, the FCBGA package 1 of the invention comprises a substrate 10 having a first surface 10a and an opposing second surface 10b; at least one semiconductor chip 11 having an active surface 11a attached on the first surface 10a of the substrate 10 for electrically connecting with the substrate 10; a ring stiffener 20 attached on the first surface 10a of the substrate 10, and formed with a plurality of penetrating openings 201 thereon; a heat sink 30 having a top surface 30a and an opposing bottom surface 30b attached to the non active surface of the chip 11; an adhesive 14 applied over the contact area between the first surface 10a of the substrate 10 and the ring stiffener 20, and filling in the plurality of penetrating openings 201 of the ring stiffener 20; and a plurality of solder balls 13 mounted on the second surface 10b of the substrate 10.

The heat sink 30 is a metal plate of 20-40 mils thickness, made of a Ni-plated copper material. The ring stiffener 20 is made of the same material as the heat sink 30, so as to avoid differences in the coefficients of thermal expansion (CTE) of the two, thereby preventing warpage or delamination. Moreover, since the CTE of the Ni-plated copper material is very close to that of the substrate (such as epoxy resin, BT resin or FR4 resin), the possibilities of warpage or delamination between the ring stiffener 20 and the substrate 10 are reduced to a very low level.

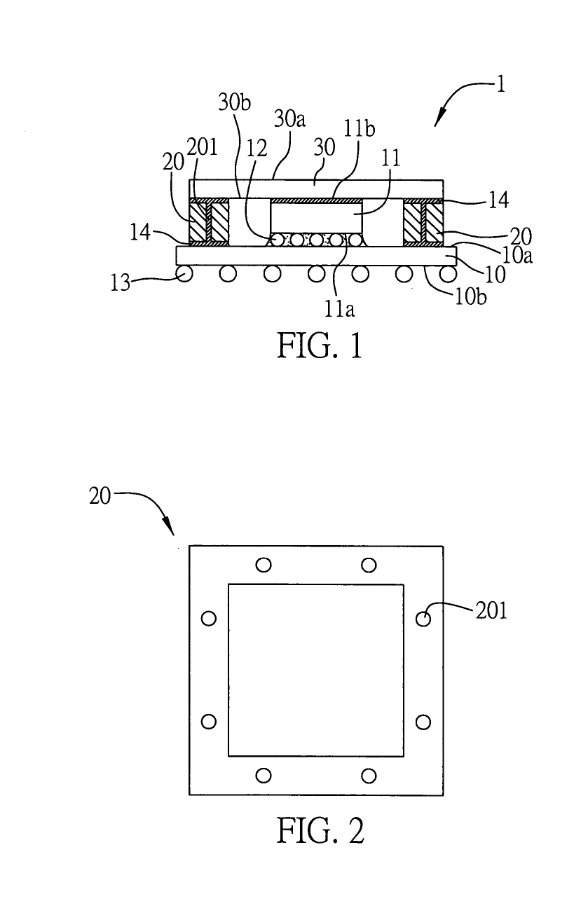

As shown in FIG. 2, the ring stiffener 20 is composed of 4 strips that are assembled as a square which, together, are attached to the first surface 10a of the substrate. A plurality of penetrating openings 201 penetrating from the first surface 10a of the substrate 10 to the bottom surface 30b of the heat sink 30 are formed on the ring stiffener 20. Accordingly, when the ring stiffener 20 is attached to the substrate 10 and the heat sink 30 is attached to the ring stiffener 20, the adhesive applied thereon is forced to fill in these penetrating openings 201 that in turn provide an extra bonding force in addition to the bonding surface to allow the heat sink 30 to be more firmly attached to the substrate 10, thereby inhibiting it from coming off.

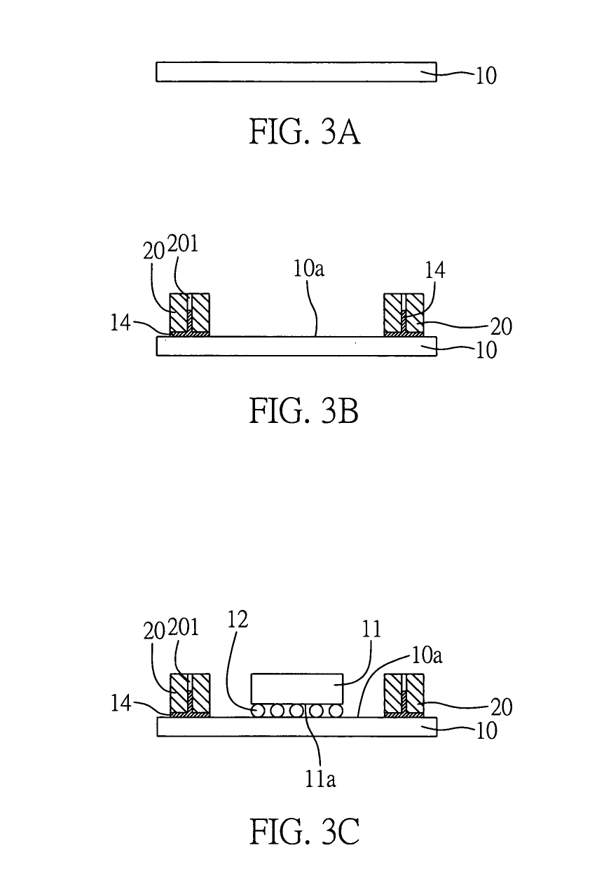

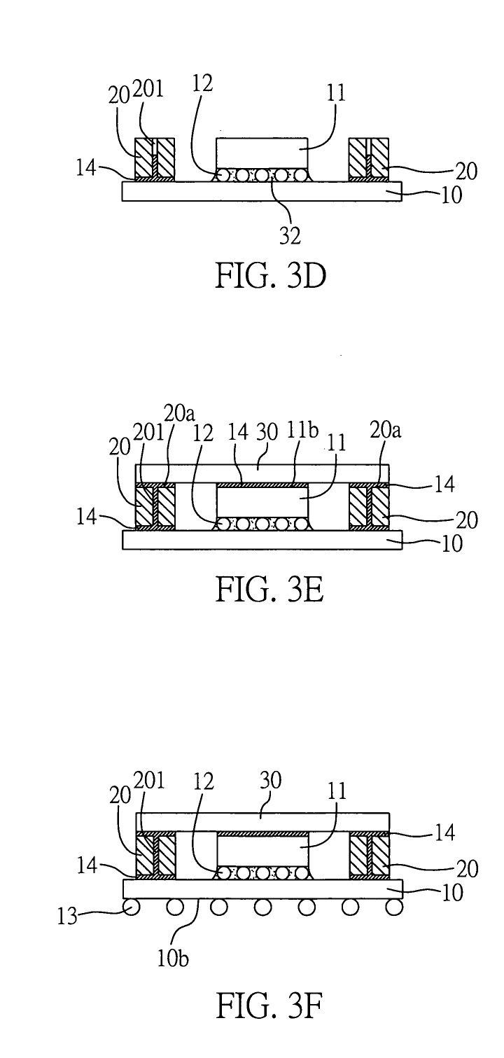

The fabricating method of the semiconductor package with the heat sink of the preferred embodiment of the present invention is shown in FIG. 3A to FIG. 3F. At first, as shown in FIG. 3A, a substrate 10 is prepared; then as shown in FIG. 3B a ring stiffener 20 is prepared with a plurality of penetrating openings 201 formed thereon and then the ring stiffener 20 is attached to the first surface 10 of the substrate 10 by applying an adhesive between the ring stiffener and the first surface 10 of the substrate 10. Upon pressing together, the adhesive is forced to go into the penetrating openings 201 formed on the stiffener 20. After the ring stiffener 20 is attached on the substrate 10, a defined area embraced by the ring stiffener 20 is formed. Subsequently, as shown in FIG. 3C, a semiconductor chip 11 is attached to the defined area embraced by the ring stiffener 20 on the substrate 10 via a plurality of conductive bumps 12 in an upside down manner. The thickness of the chip 11 is approximately the same as the ring stiffener 20. A reflow process is then applied to electrically connect the chip 11 to the substrate 10 via the conductive bumps 12. After the chip 11 is electrically connected to the substrate 10, a washing step is performed to wash out the excessive flux. Then, as shown in FIG. 3D, an underfill material 32 is filled in between each of the conductive bumps 12 and subjected to a curing process to prevent the conductive bumps 12 from cracking. Subsequently, as shown in FIG. 3E, a thermally conductive adhesive material 14 is applied on both the top surface 20a of the ring stiffener 20 and the non-active surface 11b of the chip 11 to attach the heat sink 30 onto both the chip 11 and the ring stiffener 20, allowing the flange of the heat sink 30 to be flush with that of the ring stiffener 20. The applied adhesive 14 is again forced to go into the penetrating openings 201 of the ring stiffener 20. Finally, as shown in FIG. 3F, a plurality of solder balls 13 are mounted on the second surface 10b of the substrate, for electrically connecting the substrate 10 to an external PC board (not shown) via a plurality of conductive vias (not shown).

Thus, through the formation of the penetrating openings 201 on the ring stiffener 20, the heat sink 30 can be more firmly attached to the ring stiffener 20 via the adhesive filling in the penetrating openings 201. In addition, these penetrating openings also increase the surface area of the adhesive thereby significantly enhancing the bonding strength of the heat sink 30, such that the heat sink 30 can be inhibited from detaching from the substrate 10 or the ring stiffener 20, without the need to redesign the patterned circuit on the substrate, and thus making the overall manufacturing procedures cost-effective and simple.

Additionally, since the chip 11 is attached to the bottom surface 30b of the heat sink via a thermally conductive adhesive material 14, the heat generated by the chip during operation can be easily transferred to the heat sink 30 and dissipated to the ambient environment.

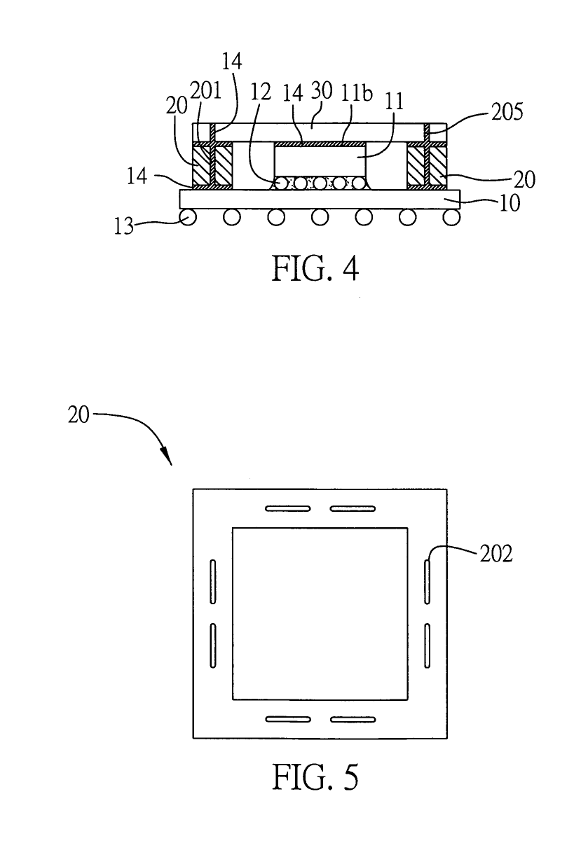

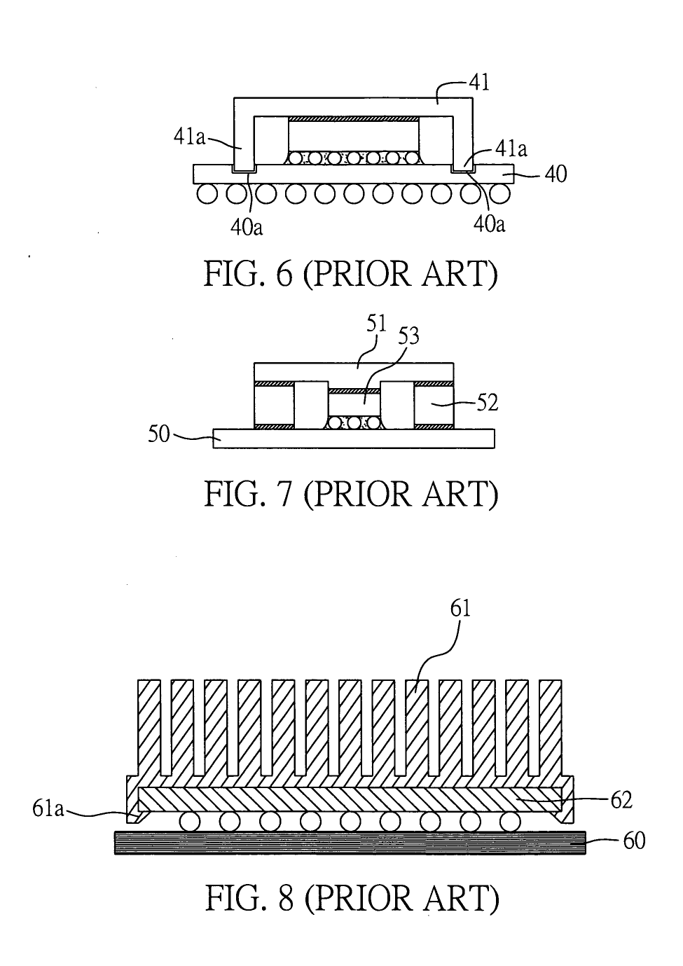

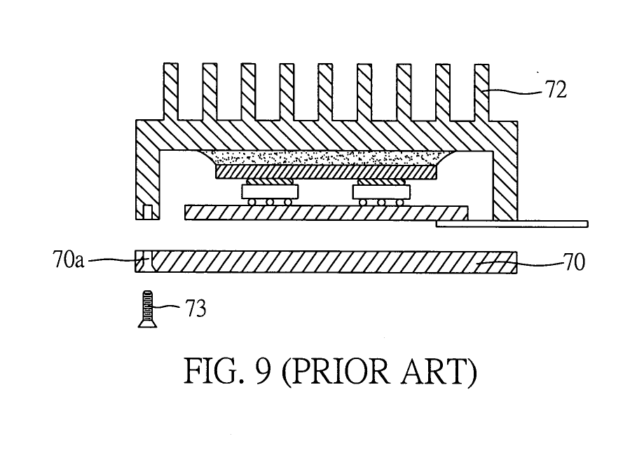

As shown in FIG. 4, in addition to the semiconductor package 1 disclosed by the foregoing embodiment of the present invention, a second preferred embodiment shows that a plurality of penetrating openings 205 can also be formed on the periphery of the heat sink 30 so as to further enhance the bonding strength of the heat sink. At bonding time, the adhesive applied between the ring stiffener 20 and the non-active surface 11b of the chip 11 is also forced to fill in the penetrating openings 205 on the heat sink 30, thus further enhancing the bonding strength of the heat sink 30.

The number and the positioning of the penetrating openings 201 are not specifically limited; however, the positioning is preferably to be symmetrical to evenly distribute the bonding force of the heat sink 30 for satisfactory bonding. Similarly, the shape of the penetrating openings 201 is not limited to a particular shape, and various shapes for the penetrating openings 201 can be formed using different punch heads, as exemplified in FIG. 5 where the penetrating openings 202 are rectangular grooves, providing the same bonding effect to the heat sink 30 as the circular opening depicted earlier.

Similarly, the ring stiffener 20 is not limited to the foregoing square ring design; various other shapes and arrangements for the ring stiffener are also applicable to the present invention. Moreover, the adhesion material 13 for attaching ring stiffener 20 and the heat sink 30 can be changed to other materials, as long as this material can fill in the penetrating openings 201, 201, and 205 to enhance bonding.

Furthermore, the semiconductor package with the heat sink disclosed in the foregoing embodiment of the present invention is also applicable to other packages such as wire-bonding type packages which are well known to those skilled in art, and thus are not described herein.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

1. A semiconductor package with a heat sink, comprising:
a substrate having a first surface and an opposing second surface;
at least one semiconductor chip having an active surface and an opposing non-active surface, wherein the active surface of the chip is attached and electrically connected to the first surface of the substrate;
at least one stiffener having a plurality of penetrating openings and mounted on the first surface of the substrate to embrace the chip therein;
a heat sink attached to the stiffener; and
an adhesive material filled in the plurality of penetrating openings for attaching the stiffener to the substrate and attaching the heat sink to the stiffener respectively.

2. The semiconductor package of claim 1, further comprising a plurality of solder balls mounted on the second surface of the substrate.

3. The semiconductor package of claim 1, wherein the plurality of penetrating openings are penetrating vias.

4. The semiconductor package of claim 1, wherein the plurality of penetrating openings are penetrating grooves.

5. The semiconductor package of claim 1, wherein the heat sink is further formed with a plurality of openings to allow the adhesive material to be filled therein.

6. The semiconductor package of claim 1, wherein the stiffener is formed as a square ring to surround the chip.

7. The semiconductor package of claim 1, wherein the heat sink covers the chip.

8. The semiconductor package of claim 1, wherein a conductive adhesive is applied over the non-active surface of the chip to attach the heat sink thereon.

9. The semiconductor package of claim 1, wherein the semiconductor package is a FCBGA (flip-chip ball grid array) package.

10. A fabricating method for a semiconductor package with a heat sink, comprising the steps of:
preparing a substrate having a first surface and an opposing second surface;
preparing a stiffener formed with a plurality of penetrating openings thereon;
applying an adhesive material to attach the stiffener to the substrate in a manner that the adhesive material is filled in the plurality of penetrating openings and a predefined area on the first surface of the substrate is embraced by the stiffener;
preparing at least one chip, and attaching and electrically connecting an active-surface of the chip to the first surface of the substrate in a manner that the chip is accommodated in the predefined area embraced by the stiffener; and
applying an adhesive material to attach a heat sink to the stiffener and allowing the adhesive material to be filled in the plurality of the penetrating openings.

11. The fabricating method of claim 10, further comprising mounting a plurality of solder balls on the second surface of the substrate.

12. The fabricating method of claim 10, wherein the penetrating openings are penetrating vias.

13. The fabricating method of claim 10, wherein the penetrating openings are penetrating grooves.

14. The fabricating method of claim 10, wherein the heat sink is further formed with a plurality of openings to allow the adhesive material to be filled therein.

15. The fabricating method of claim 10, wherein the stiffener is formed as a square ring to surround the chip.

16. The fabricating method of claim 10, wherein the heat sink covers the chip.

17. The fabricating method of claim 10, wherein a conductive adhesive is applied over a non-active surface of the chip to attach the heat sink thereon.

18. The fabricating method of claim 10, wherein the semiconductor package is a FCBGA (flip-chip ball grid array) package.

19. A stiffener for a semiconductor package, comprising:
a plurality of supporting parts having a plurality of penetrating openings and embracing a predefined space for receiving a chip in the semiconductor package therein.

20. The stiffener of claim 19, wherein the supporting parts are for supporting a heat sink in the semiconductor package.

21. The stiffener of claim 19, wherein the penetrating openings are penetrating vias.

22. The stiffener of claim 19, wherein the penetrating openings are penetrating grooves.

23. The stiffener of claim 19, wherein the plurality of supporting parts embrace a square space to surround the chip.

24. The stiffener of claim 19, wherein the semiconductor package is a FCBGA (flip-chip ball grid array) package.
